(19) United States
(12) Patent Application Publication
(10) Pub. No.: US 2013/0161569 A1
(43) Pub. Date: Jun. 27, 2013

(54) GLASS FOR USE IN FORMING ELECTRODES, AND ELECTRODE-FORMING MATERIAL USING SAME

(71) Applicant: Kentaro Ishihara, Shiga (JP)

(72) Inventor: Kentaro Ishihara, Shiga (JP)

(21) Appl. No.: 13/817,339

(22) PCT Filed: Jul. 29, 2011
(86) PCT No.: PCT/JP2011/067472

§ 371 Date: Mar. 7, 2013

(30) Foreign Application Priority Data
Aug. 17, 2010 (JP) 2010-182070
Aug. 26, 2010 (JP) 2010-188992

(51) Int. Cl. H01L 31/0224

(52) U.S. Cl. CPC H01L 31/022425
USPC 252/501.1; 501/49; 501/50; 501/41; 501/73; 501/77; 501/78; 501/79

(57) ABSTRACT

Provided is a glass for electrode formation, comprising, as a glass composition in terms of mass %, 65.2 to 90% of Bi₂O₃, 0 to 5.4% of B₂O₃, and 0.1 to 34.5% of MgO+CaO+SrO+BaO+ZnO+CuO+Fe₂O₃+Nd₂O₃+CeO₂+Sb₂O₃ (total content of MgO, CaO, SrO, BaO, ZnO, CuO, Fe₂O₃, Nd₂O₃, CeO₂, and Sb₂O₃).

### TECHNICAL FIELD

The present invention relates to a glass for electrode formation and an electrode formation material, and more particularly, to a glass for electrode formation and an electrode formation material suited for forming a light-receiving surface electrode of a silicon solar cell (including a monocrystalline silicon solar cell, a polycrystalline silicon solar cell, and a microcrystalline silicon solar cell) having an anti-reflective film.

### BACKGROUND ART

A silicon solar cell is provided with a semiconductor substrate, a light-receiving surface electrode, a back-surface electrode, and an anti-reflective film. The semiconductor substrate has a p-type semiconductor layer and an n-type semiconductor layer. The light-receiving surface electrode, which has a grid shape, is formed on the semiconductor substrate on the light-receiving surface side, and the back-surface electrode is formed on the semiconductor substrate on the back-surface side (non-light-receiving surface side). The light-receiving surface electrode and the back-surface electrode are formed by sintering an electrode formation material (including metal powder, glass powder, and a vehicle). In general, Ag powder is used for the light-receiving surface electrode and Al powder is used for the back-surface electrode. A silicon nitride film, a silicon oxide film, a titanium oxide film, an aluminum oxide film, or the like is used for the anti-reflective film. The silicon nitride film is mainly used at present.

As a method of forming a light-receiving surface electrode in a silicon solar cell, there are known a vapor deposition method, a plating method, a printing method, and the like. The printing method has recently become mainstream. The printing method is a method of forming a light-receiving surface electrode by applying an electrode formation material onto an anti-reflective film or the like by screen printing, and then firing the electrode formation material at 650 to 850° C. for a short time.

In the case of the printing method, through utilization of such a phenomenon that the electrode formation material penetrates the anti-reflective film at the time of the firing, the light-receiving surface electrode is electrically connected to a semiconductor layer. The phenomenon is generally referred to as fire through. Through utilization of the fire through, it becomes unnecessary to etch the anti-reflective film, and moreover, it becomes unnecessary to position an etching on the anti-reflective film with an electrode pattern, when the light-receiving surface electrode is formed. As a result, production efficiency of the silicon solar cell improves dramatically.

### CITATION LIST

### Patent Literature

Patent Literature 1: JP 2004-87951 A
Patent Literature 2: JP 2005-56875 A
Patent Literature 3: JP 2008-527698 A

### SUMMARY OF INVENTION

### Technical Problem

The degree of how much an electrode formation material penetrates an anti-reflective film (hereinafter, referred to as fire through property) varies depending on the composition of the electrode formation material and a firing condition, and in particular, is influenced most significantly by the glass composition of glass powder. This is because the fire through is mainly caused by a reaction between the glass powder and the anti-reflective film. In addition, the photoelectric conversion efficiency of a silicon solar cell has a correlation with the fire through property of the electrode formation material. When the fire through property is poor, the photoelectric conversion efficiency of the silicon solar cell lowers. As a result, the fundamental performance of the silicon solar cell lowers.

Further, a bismuth-based glass having a particular glass composition exhibits satisfactory fire through property, but even if such bismuth-based glass is used, a failure causing the deterioration of the photoelectric conversion efficiency of the silicon solar cell occurs at the time of the fire through in some cases. Thus, the bismuth-based glass still has room for improvement from the viewpoint of enhancing the photoelectric conversion efficiency of the silicon solar cell.

In addition, glass powder comprised in an electrode formation material is required to have characteristics such as being able to be sintered at low temperature.

Thus, a technical object of the present invention is to invent a bismuth-based glass which has satisfactory fire through property, is unlikely to deteriorate the photoelectric conversion efficiency of a silicon solar cell at the time of fire through, and can be sintered at low temperature, to thereby enhance the photoelectric conversion efficiency of the silicon solar cell.

### Solution to Problem

The inventor of the present invention has made intensive studies. As a result, the inventor has found that the technical object can be achieved by controlling the glass composition of a bismuth-based glass within a predetermined range, in particular, controlling the contents of Bi₂O₃ and B₂O₃ within a predetermined range. Thus, the finding is proposed as the present invention. That is, a glass for electrode formation of the present invention comprises, as a glass composition in terms of mass %, 65.2 to 90% of Bi₂O₃, 0 to 5.4% of B₂O₃, and 0.1 to 34.5% of MgO+CaO+SrO+BaO+ZnO+CuO+Fe₂O₃+Nd₂O₃+CeO₂+Sb₂O₃ (total content of MgO, CaO, SrO, BaO, ZnO, CuO, Fe₂O₃, Nd₂O₃, CeO₂, and Sb₂O₃).

In the glass for electrode formation of the present invention, the content of Bi₂O₃ is controlled to 65.2 mass % or more. With this, the reactivity between the glass powder and the anti-reflective film is enhanced, the fire through property is improved, and the softening point lowers. As a result, the electrode formation material can be sintered at low temperature. Note that when the electrode is formed at low temperature, the productivity of the silicon solar cell is improved and the release of hydrogen in the crystalline boundary of the semiconductor substrate becomes unlikely to occur, and hence the photoelectric conversion efficiency of the silicon solar cell is improved. Further, when the content of Bi₂O₃ is controlled to 65.2 mass % or more, the water resistance is improved and the long-term reliability of the silicon solar cell can be enhanced. On the other hand, in the glass for electrode formation of the present invention, the content of Bi₂O₃ is controlled to 90 mass % or less. With this, glass becomes unlikely to denitrify at the time of firing. As a result, the reactivity between the glass powder and the anti-reflective film becomes unlikely to lower and the sintering property of the electrode formation material becomes unlikely to lower.

Further, in the glass for electrode formation of the present invention, the content of B₂O₃ is controlled to 5.4 mass % or less. The inventor of the present invention has made intensive studies. As a result, the inventor has found that B₂O₃ in the glass composition causes the deterioration of the photoelectric conversion efficiency of a silicon solar cell at the time of fire through, particularly found that B₂O₃ contributes to the formation of a boron-containing different-type layer in a semiconductor layer on the light-receiving surface side at the time of fire through, thereby deteriorating functions of a p-type semiconductor layer and an n-type semiconductor layer in a semiconductor substrate, and found that such a failure as described above can be suppressed by controlling the content of B₂O₃ to 5.4 mass % or less in the glass composition. Further, when the content of B₂O₃ is controlled to 5.4 mass % or less, the softening point lowers, thus enabling an electrode formation material to be sintered at low temperature, and the water resistance improves, thereby being able to enhance the long-term reliability of the silicon solar cell.

On the other hand, when the content of B₂O₃ in glass is controlled as described above, the content of a glass constituent component lowers, and hence the glass is liable to devitrify at the time of firing. Thus, in the glass for electrode formation of the present invention, the content of MgO+CaO+SrO+BaO+ZnO+CuO+Fe₂O₃+Nd₂O₃+CeO₂+Sb₂O₃ is controlled to 0.1 mass % or more. With this, the glass is unlikely to devitrify at the time of firing an electrode formation material comprising the glass, and hence the reactivity between glass powder and an anti-reflective film is unlikely to deteriorate and the sintering property of the electrode formation material is unlikely to deteriorate. On the other hand, in the glass for electrode formation of the present invention, the content of MgO+CaO+SrO+BaO+ZnO+CuO+Fe₂O₃+Nd₂O₃+CeO₂+Sb₂O₃ is controlled to 34.5 mass % or more. With this, an unreasonable increase in softening point can be suppressed, and hence an electrode formation material can be sintered at low temperature.

Second, it is preferred that the glass for electrode formation of the present invention have a content of B₂O₃ of less than 1.9 mass %.

Third, it is preferred that the glass for electrode formation of the present invention be substantially free of B₂O₃. Herein, the phrase “substantially free of B₂O₃” refers to the case where the content of B₂O₃ is less than 0.1 mass %.

Fourth, it is preferred that the glass for electrode formation of the present invention further comprise 0.1 to 15 mass % of SiO₂+Al₂O₃ (total content of SiO₂ and Al₂O₃). With this, the glass is unlikely to denitrify at the time of firing, and hence the reactivity between glass powder and an anti-reflective film is unlikely to deteriorate and the sintering property of the electrode formation material is unlikely to deteriorate. Note that when the content of SiO₂+Al₂O₃ is controlled to 15 mass % or less, an unreasonable increase in softening point is easily prevented.

Fifth, it is preferred that the glass for electrode formation of the present invention be substantially free of PbO. With this, an environmental request in recent years can be satisfied. Herein, the phrase “substantially free of PbO” refers to the case where the content of PbO is less than 0.1 mass %.

Sixth, the electrode formation material of the present invention comprises glass powder comprising the above-mentioned glass for electrode formation, metal powder, and a vehicle. With this, an electrode pattern can be formed by a printing method, and hence the production efficiency of the silicon solar cell can be enhanced. Herein, the term “vehicle” generally refers to a substance obtained by dissolving a resin in an organic solvent. However, in the present invention, the term “vehicle” includes, as one aspect, a substance that does not contain a resin and is formed of only a highly viscous organic solvent (for example, a higher alcohol such as isotridecyl alcohol).

Seventh, it is preferred that the electrode formation material of the present invention have glass powder having an average particle diameter D₅₀ of less than 5 μm. With this, the reactivity between the glass powder and the anti-reflective film is enhanced, the fire through property is improved, the softening point of the glass powder lowers, and hence the electrode formation material can be sintered at low temperature. Further, a very fine electrode pattern can be formed. Note that when the very fine electrode pattern is formed, the amount of incident solar light or the like increases and the photoelectric conversion efficiency of the silicon solar cell is improved. Herein, the term “average particle diameter D₅₀” refers to a particle diameter at which the cumulative amount of particles starting from a particle having the smallest diameter reaches 50% in a cumulative particle size distribution curve in terms of volume prepared based on measurement by laser diffractometry.

Eighth, it is preferred that the electrode formation material of the present invention have glass powder having a softening point of 550° C. or less. Note that the softening point may be measured with a macro-type differential thermal analysis (DTA) apparatus. When the softening point is measured by macro-type DTA, the measurement starts from room temperature and the temperature rise rate has only to be set to 10° C./min. Note that the softening point in the macro-type DTA corresponds to a temperature (Ts) at the fourth bending point illustrated in FIG. 1.

Ninth, it is preferred that the electrode formation material of the present invention have a content of the glass powder of 0.2 to 10 mass %. With this, the conductivity of an electrode can be enhanced while the sintering property of the electrode formation material is maintained.

Tenth, it is preferred that the electrode formation material of the present invention have metal powder comprising one kind of powder or two or more kinds of powders of Ag, Al, Au, Cu, Pd, Pt, and alloys thereof. Any of those metal powders has satisfactory compatibility with the bismuth-based glass according to the present invention and has the property of preventing the easy bubbling of the glass at the time of firing.

Eleventh, it is preferred that the electrode formation material of the present invention be used for an electrode of the silicon solar cell.

Twelfth, it is preferred that the electrode formation material of the present invention be used for the light-receiving surface electrode of a silicon solar cell having an anti-reflective film.

### BRIEF DESCRIPTION OF DRAWINGS

FIG. 1 A schematic view illustrating a softening point Ts as measured by macro-type DTA.

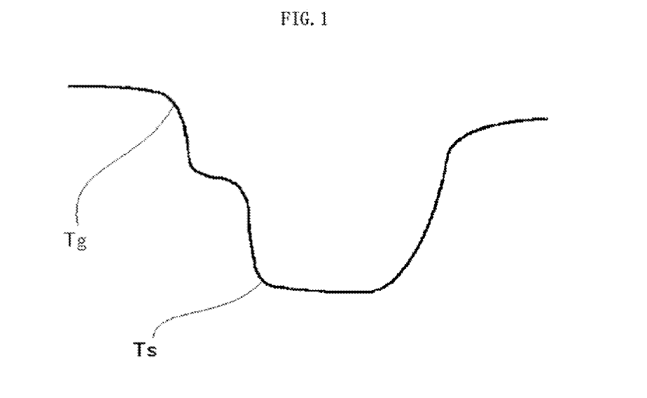

### DESCRIPTION OF EMBODIMENTS

### First Embodiment of the Present Invention

A glass for electrode formation according to the first embodiment of the present invention comprises, as a glass composition in terms of mass %, 65.2 to 90% of Bi₂O₃, 0 to 5.4% of B₂O₃, and 0.1 to 34.5% of MgO+CaO+SrO+BaO+ZnO+CuO+Fe₂O₃+Nd₂O₃+CeO₂+Sb₂O₃.

The reasons why the content ranges of the respective components were limited to those described above are as described below. Note that in the description about the glass composition, “%” refers to “mass %.”

Bi₂O₃ is a component that enhances the fire through property and water resistance of glass and a component that lowers the softening point thereof. The content of Bi₂O₃ is 65.2 to 90%, preferably 70 to 86%, more preferably 75 to 82%, still more preferably 76 to 80%. When the content of Bi₂O₃ is less than 65.2% in glass, the fire through property and water resistance of the glass lower, and moreover, the softening point thereof becomes too high, with the result that it is difficult to sinter an electrode formation material comprising the glass at low temperature. On the other hand, when the content of Bi₂O₃ is more than 90% in glass, the glass is liable to denitrify at the time of firing. Owing to the denitrification, the reactivity between glass powder and an anti-reflective film and the sintering property of an electrode formation material are liable to deteriorate.

B₂O₃ is a glass-forming component and a component that lowers the photoelectric conversion efficiency of a silicon solar cell at the time of fire through. The content of B₂O₃ is preferably 5.4% or less, 3% or less, less than 2%, less than 1.9%, 1.8% or less, 1% or less, less than 1%, 0.5% or less, 0.3% or less, particularly preferably less than 0.1%. When the content of B₂O₃ is more than 5.4%, boron is doped in a semiconductor layer on the light-receiving surface side at the time of fire through, resulting in the formation of a boron-containing different-type layer. Thus, the functions of a p-type semiconductor layer and an n-type semiconductor layer in a semiconductor substrate are liable to deteriorate, with the result that the photoelectric conversion efficiency of a silicon solar cell is liable to deteriorate. Further, when the content of B₂O₃ is more than 5.4% in glass, the viscosity of the glass tends to increase, with the result that it is difficult to sinter an electrode formation material comprising the glass at low temperature, the water resistance is liable to lower, and the long-term reliability of a silicon solar cell is liable to lower.

MgO+CaO+SrO+BaO+ZnO+CuO+Fe₂O₃+Nd₂O₃+CeO₂+Sb₂O₃ are components that enhance the thermal stability of glass. The content of MgO+CaO+SrO+BaO+ZnO+CuO+Fe₂O₃+Nd₂O₃+CeO₂+Sb₂O₃ is 0.1 to 34.5%, preferably 0.5 to 30%, more preferably 1 to 20%, still more preferably to 15%. When the content of MgO+CaO+SrO+BaO+ZnO+CuO+Fe₂O₃+Nd₂O₃+CeO₂+Sb₂O₃ is less than 0.1% in glass, the glass is liable to denitrify at the time of firing. Owing to the denitrification, the reactivity between glass powder and an anti-reflective film and the sintering property of an electrode formation material comprising the glass are liable to deteriorate. On the other hand, when the content of MgO+CaO+SrO+BaO+ZnO+CuO+Fe₂O₃+Nd₂O₃+CeO₂+Sb₂O₃ is more than 34.5% in glass, the softening point becomes too high, with the result that it is difficult to sinter an electrode formation material comprising the glass at low temperature.

MgO is a component that enhances the thermal stability. The content of MgO is preferably 0 to 5%, particularly preferably 0 to 2%. When the content of MgO is more than 5% in glass, the softening transition point thereof becomes too high, with the result that it is difficult to sinter an electrode formation material comprising the glass at low temperature.

CaO is a component that enhances the thermal stability of glass. The content of CaO is preferably 0 to 5%, particularly preferably 0 to 2%. When the content of CaO is more than 5% in glass, the softening point thereof becomes too high, with the result that it is difficult to sinter an electrode formation material comprising the glass at low temperature.

SrO is a component that enhances the thermal stability of glass. The content of SrO is preferably 0 to 15%, 0 to 10%, particularly preferably 0 to 7%. When the content of SrO is more than 15% in glass, the softening point thereof becomes too high, with the result that it is difficult to sinter an electrode formation material comprising the glass at low temperature.

Out of the alkaline-earth metal oxides, BaO exhibits an effect of enhancing the thermal stability most significantly, and moreover, has an effect of resisting the increase of the softening point, and hence it is preferred that BaO be positively added to a glass composition. The content of BaO is 0 to 20%, 0.1 to 17%, 2 to 15%, particularly preferably 4 to 12%. When the content of BaO is more than 20% in glass, the balance of components in a glass composition is lost, with the result that the thermal stability of the glass is liable to lower to the worse.

ZnO is a component that enhances the thermal stability of glass and is also a component that lowers the softening point thereof without lowering the thermal expansion coefficient thereof. The content of ZnO is preferably 0 to 25%, 1 to 16%, particularly preferably 2 to 12%. When the content of ZnO is more than 25% in glass, the balance of components in a glass composition is lost, with the result that crystals are liable to precipitate in the glass to the worse.

CuO is a component that enhances the thermal stability of glass. The content of CuO is preferably 0 to 15%, 0.1 to 10%, particularly preferably 1 to 10%. When the content of CuO is more than 15% in glass, the balance of components in a glass composition is lost, with the result that the precipitation rate of crystals becomes higher, that is, the thermal stability of the glass tends to deteriorate to the worse. In order to enhance the fire through property of glass, Bi₂O₃ needs to be added in a large amount in a glass composition. However, when the content of Bi₂O₃ is increased in glass, the glass is liable to denitrify at the time of firing. Owing to the devitrification, the reactivity between glass powder and an anti-reflective film is liable to deteriorate. Particularly when the content of Bi₂O₃ is 70% or more in glass, the tendency becomes remarkable. Thus, when CuO is added in an appropriate extent in a glass composition, the devitrification of the glass can be suppressed even if the content of Bi₂O₃ is 70% or more.

Fe₂O₃ is a component that enhances the thermal stability of glass. The content of Fe₂O₃ is preferably 0 to 5%, particularly preferably 0 to 2%. When the content of Fe₂O₃ is more than 5% in glass, the balance of components in a glass composition is lost, with the result that the precipitation rate of crystals becomes higher, that is, the thermal stability of the glass tends to deteriorate to the worse.

Nd₂O₃ is a component that enhances the thermal stability of glass. The content of Nd₂O₃ is 0 to 10%, particularly preferably 0 to 3%. When Nd₂O₃ is added in a predetermined amount in a glass composition, the glass network of Bi₂O₃—B₂O₃ is stabilized. As a result, crystals of Bi₂O₃ (bismite) or crystals of 2Bi₂O₃.B₂O₃, 12Bi₂O₃.B₂O₃, or the like formed of Bi₂O₃ and B₂O₃ become unlikely to precipitate at the time of firing. Note that when the content of Nd₂O₃ is more than 10% in glass, the balance of components in a glass composition is lost, with the result that the crystals are liable to precipitate in the glass to the worse.

CeO₂ is a component that enhances the thermal stability of glass. The content of CeO₂ is preferably 0 to 5%, particularly preferably 0 to 2%. When the content of CeO₂ is more than 5% in glass, the balance of components in a glass composition is lost, with the result that the precipitation rate of crystals becomes higher, that is, the thermal stability of the glass tends to deteriorate to the worse.

Sb₂O₃ is a component that enhances the thermal stability of glass. The content of Sb₂O₃ is 0 to 7%, 0.1 to 5%, particularly preferably 0.3 to 3%. When the content of Sb₂O₃ is more than 7% in glass, the balance of components in a glass composition is lost, with the result that the precipitation rate of crystals becomes higher, that is, the thermal stability of the glass tends to deteriorate to the worse. In order to enhance the fire through property of glass, Bi₂O₃ needs to be added in a large amount in a glass composition. However, when the content of Bi₂O₃ is increased in glass, the glass is liable to denitrify at the time of firing. Owing to the devitrification, the reactivity between glass powder and an anti-reflective film is liable to deteriorate. Particularly when the content of Bi₂O₃ is 70% or more in glass, the tendency becomes remarkable. Thus, when Sb₂O₃ is added in an appropriate amount in a glass composition, the devitrification of the glass can be suppressed even if the content of Bi₂O₃ is 70% or more.

In addition to the above-mentioned components, for example, the following components may be added.

SiO₂+Al₂O₃ are components that enhance the water resistance of glass. The content of SiO₂+Al₂O₃ is preferably 0 to 20%, 0.1 to 15%, particularly preferably 5 to 12%. When the content of SiO₂+Al₂O₃ is more than 20% in glass, the softening point thereof becomes too high, with the result that it is difficult to sinter an electrode formation material comprising the glass at low temperature, and moreover, the fire through property of the glass tends to lower.

SiO₂ is a component that enhances the water resistance of glass and a component that enhances the bonding strength between a semiconductor substrate and an electrode. The content of SiO₂ is preferably 0 to 20%, 0.1 to 15%, particularly preferably 1 to 10%. When the content of SiO₂ is more than 20% in glass, the softening point thereof becomes too high, with the result that it is difficult to sinter an electrode formation material comprising the glass at low temperature, and moreover, the fire through property of the glass tends to lower.

Al₂O₃ is a component that enhances the water resistance of glass and a component that enhances the photoelectric conversion efficiency of a silicon solar cell. The content of Al₂O₃ is preferably 0 to 15%, 0.1 to 10%, particularly preferably 1 to 8%. When the content of Al₂O₃ is more than 15% in glass, the softening point thereof becomes too high, with the result that it is difficult to sinter an electrode formation material comprising the glass at low temperature, and moreover, the fire through property of the glass tends to lower. Note that the reasons why the addition of Al₂O₃ in glass improves the photoelectric conversion efficiency of the silicon solar cell have not been clarified. The inventor presumes at present that the addition of Al₂O₃ in glass may inhibit the formation of a different-type layer in a semiconductor layer on the light-receiving surface side at the time of the fire through of the glass.

Li₂O, Na₂O, K₂O, and Cs₂O are components that lower the softening point of glass, but have an action of promoting the denitrification of glass at the time of melting. Thus, the content of each of Li₂O, Na₂O, K₂O, and Cs₂O is preferably 2% or less.

WO₃ is a component that enhances the thermal stability of glass. The content of WO₃ is 0 to 5%, particularly preferably 0 to 2%. When the content of WO₃ is more than 5% in glass, the balance of components in a glass composition is lost, with the result that the thermal stability of the glass is liable to lower to the worse.

In₂O₃+Ga₂O₃ (total content of In₂O₃ and Ga₂O₃) are components that enhance the thermal stability of glass. The content of In₂O₃+Ga₂O₃ is 0 to 5%, 0 to 3%, particularly preferably 0 to 1%. When the content of In₂O₃+Ga₂O₃ is more than 5% in glass, the batch cost of the glass is liable to soar. Note that the content of each of In₂O₃ and Ga₂O₃ is preferably 0 to 2%.

P₂O₅ is a component that suppresses the denitrification of glass at the time of melting. However, when the content of P₂O₅ is large in glass, the phase separation of the glass is liable to occur at the time of melting. Thus, the content of P₂O₅ is preferably 1% or less.

MoO₃+La₂O₃+Y₂O₃ (total content of MoO₃, La₂O₃, and Y₂O₃) have an effect of suppressing the phase separation at the time of melting. However, when the content of those components is large in glass, the softening point of the glass becomes too high, with the result that it is difficult to sinter an electrode formation material comprising the glass at low temperature. Thus, the content of MoO₃+La₂O₃+Y₂O₃ is preferably 3% or less. Note that the content of each of MoO₃, La₂O₃, and Y₂O₃ is preferably 0 to 2%.

The glass for electrode formation (bismuth-based glass) according to the first embodiment may comprise PbO, but is preferably substantially free of PbO from the environmental viewpoint. Further, as PbO has insufficient water resistance, the glass is preferably substantially free of PbO when the glass is used for a silicon solar cell.

### Second Embodiment of the Present Invention

An electrode formation material according to the second embodiment of the present invention comprises glass powder comprising the glass for electrode formation according to the first embodiment, metal powder, and a vehicle. The glass powder is a component that causes the fire through of an electrode formation material by eroding an anti-reflective film at the time of firing and is also a component that bonds an electrode to a semiconductor substrate. The metal powder is a main component for forming an electrode and a component for securing conductivity. The vehicle is a component for converting the state of the electrode formation material into a paste form and a component for imparting viscosity suitable for printing to the paste material.

In the electrode formation material according to the second embodiment, the average particle diameter D₅₀ of the glass powder is preferably less than 5 μm, 4 μm or less, 3 μm or less, 2 μm or less, particularly preferably 1.5 μm or less. When the average particle diameter D₅₀ of the glass powder is 5 μm or more, the surface area of the glass powder becomes small. Because of this fact, the reactivity between the glass powder and the anti-reflective film lowers and the fire through property is liable to lower. Further, when the average particle diameter D₅₀ of the glass powder is 5 μm or more, the softening point of the glass powder rises and the range of temperatures necessary for forming an electrode rises. Moreover, when the average particle diameter D₅₀ of the glass powder is 5 μm or more, the formation of a fine electrode pattern becomes difficult, and hence the photoelectric conversion efficiency of the silicon solar cell is liable to lower. On the other hand, although the lower limit of the average particle diameter D₅₀ of the glass powder is not particularly limited, when the average particle diameter D₅₀ of the glass powder is too small, the handleability of the glass powder lowers and the material yield of the glass powder lowers. In addition to the foregoing, the glass powder is liable to aggregate, and hence the characteristics of the silicon solar cell are liable to vary. When the circumstances described above are taken into consideration, the average particle diameter D₅₀ of the glass powder is preferably 0.5 μm or more. Note that (1) when a glass film is pulverized in a ball mill and the resultant glass powder is then subjected to air classification, or (2) when a glass film is roughly pulverized in a ball mill or the like and the resultant glass is then subjected to wet pulverization in a bead mill or the like, the glass powder having the above-mentioned average particle diameter D₅₀ can be obtained.

In the electrode formation material according to the second embodiment, the maximum particle diameter Dₘₐₓ of the glass powder is preferably 25 μm or less, 20 μm or less, 15 μm or less, particularly preferably 10 μm or less. When the maximum particle diameter Dₘₐₓ of the glass powder is more than 25 μm, the formation of a fine electrode pattern becomes difficult, with the result that the photoelectric conversion efficiency of a silicon solar cell is liable to lower. Herein, the term “maximum particle diameter Dₘₐₓ” refers to a particle diameter at which the cumulative amount of particles starting from a particle having the smallest diameter reaches 99% in a cumulative particle size distribution curve in terms of volume prepared based on measurement by laser diffractometry.

In the electrode formation material according to the second embodiment, the softening point of the glass powder is preferably 550° C. or less, 530° C. or less, particularly preferably 400 to 500° C. When the softening point of the glass powder is more than 550° C., the range of temperatures necessary for forming an electrode rises. Note that when the softening point of the glass powder is less than 400° C., the reaction between the glass powder and the anti-reflective film progresses excessively, and hence the glass powder also erodes the semiconductor substrate. As a result, a depletion layer is damaged and the cell characteristics of the silicon solar cell may lower.

In the electrode formation material according to the second embodiment, the content of the glass powder is preferably 0.2 to 10 mass %, 1 to 6 mass %, particularly preferably 1.5 to 4 mass %. When the content of the glass powder is less than 0.2 mass %, the sintering property of the electrode formation material is liable to lower. On the other hand, when the content of the glass powder is more than 10 mass %, the conductivity of an electrode to be formed is liable to lower. As a result, it is difficult to extract electricity generated. Further, because of the same reasons as those described above, the mass ratio between the contents of the glass powder and the metal powder is preferably 0.3:99.7 to 13:87, 1.5:98.5 to 7.5:92.5, particularly preferably 2:98 to 5:95.

In the electrode formation material according to the second embodiment, the content of the metal powder is preferably 50 to 97 mass %, 65 to 95 mass %, particularly preferably 70 to 92 mass %. When the content of the metal powder is less than 50 mass %, the conductivity of an electrode to be formed lowers. As a result, the photoelectric conversion efficiency of a silicon solar cell is liable to lower. On the other hand, when the content of the metal powder is more than 97 mass %, the content of the glass powder relatively lowers, and hence the sintering property of the electrode formation material is liable to lower.

In the electrode formation material according to the second embodiment, the metal powder is preferably one kind of powder or two or more kinds of powders of Ag, Al, Au, Cu, Pd, Pt, and alloys thereof, particularly preferably Ag powder. Any of those metal powders has satisfactory conductivity and has satisfactory compatibility with the glass powder according to the present invention. Thus, when any of those metal powders is used, glass thus becomes unlikely to denitrify, and moreover, glass becomes unlikely to produce bubbles at the time of firing. Further, in order to form a fine electrode pattern, the average particle diameter D₅₀ of the metal powder is preferably 2 μm or less, particularly preferably 1 μm or less.

In the electrode formation material according to the second embodiment, the content of the vehicle is preferably 5 to 40 mass %, particularly preferably 10 to 25 mass %. When the content of the vehicle is less than 5 mass %, it is difficult to convert the electrode formation material into a paste form, and hence it is difficult to form an electrode by a printing method. On the other hand, when the content of the vehicle is more than 40 mass %, film thickness and film width are liable to vary before and after firing. As a result, it is difficult to form a desired electrode pattern.

As described above, the term “vehicle” generally refers to a substance obtained by dissolving a resin in an organic solvent. Examples of the resin which may be used include an acrylic acid ester (acrylic resin), ethylcellulose, a polyethylene glycol derivative, nitrocellulose, polymethylstyrene, polyethylene carbonate, and a methacrylic acid ester. In particular, an acrylic acid ester, nitrocellulose, andethylcellulose are preferred because of satisfactory thermolytic property. Examples of the organic solvent which may be used include N,N′-dimethylformamide (DMF), α-terpineol, a higher alcohol, γ-butyrolactone (γ-BL)s, tetralin, butyl carbitol acetate, ethyl acetate, isoamyl acetate, diethylene glycol monoethyl ether, diethylene glycol monoethyl ether acetate, benzyl alcohol, toluene, 3-methoxy-3-methylbutanol, water, triethylene glycol monomethyl ether, triethylene glycol dimethyl ether, dipropylene glycol monomethyl ether, dipropylene glycol monobutyl ether, tripropylene glycol monomethyl ether, tripropylene glycol monobutyl ether, propylene carbonate, dimethyl sulfoxide (DMSO), and N-methyl-2-pyrrolidone. In particular, α-terpineol is preferred because of high viscosity and satisfactory solubility for a resin and the like.

The electrode formation material according to the second embodiment may comprise, in addition to the above-mentioned components, a ceramic filler powder such as cordierite powder for adjusting the thermal expansion coefficient of glass, oxide powder such as NiO powder for adjusting the resistance of an electrode, a surfactant or a thickener for adjusting a paste characteristic, a pigment for adjusting outer appearance quality, and the like.

The electrode formation material according to the second embodiment is appropriate in the reactivity with a silicon nitride film, a silicon oxide film, a titanium oxide film, and an aluminum oxide film, and is particularly appropriate in the reactivity with the silicon nitride film and is excellent in fire through property. As a result, the electrode formation material can penetrate the anti-reflective film at the time of firing, and hence the light-receiving surface electrode of the silicon solar cell can be efficiently formed. Further, when the electrode formation material of the present invention is used, it is possible to suppress boron from doping in a semiconductor layer on the light-receiving surface side at the time of fire through. Thus, it is possible to prevent the situation that functions of a p-type semiconductor layer and an n-type semiconductor layer in a semiconductor substrate deteriorate owing to the formation of a boron-containing different-type layer. As a result, the photoelectric conversion efficiency of a silicon solar cell becomes unlikely to deteriorate.

The electrode formation material according to the second embodiment may also be used for forming a back-surface electrode of a silicon solar cell. The electrode formation material for forming the back-surface electrode generally comprises Al powder, glass powder, a vehicle, and the like. The back-surface electrode is generally formed by the above-mentioned printing method. The electrode formation material of the present invention can promote a reaction that Al powder reacts with Si in a semiconductor substrate, thereby forming an Al—Si alloy layer at the interface between the back-surface electrode and the semiconductor substrate, and can also promote the formation of a p+ electrolytic layer (back surface field layer, or also referred to as BSF layer) at the interface between the Al—Si alloy layer and the semiconductor substrate. The formation of the p+ electrolytic layer prevents the recombination of electrons, thereby being able to provide an effect of enhancing efficiency in collecting carriers produced, that is, the so-called BSF effect. As a result, the formation of the p+ electrolytic layer can lead to enhancement of the photoelectric conversion efficiency of the silicon solar cell. Further, when the electrode formation material of the present invention is used, the following failures can be properly prevented. That is, it is possible to prevent a failure that the reaction between Al powder and Si becomes heterogeneous, resulting in a local increase in the production amount of an Al—Si alloy, and because of the phenomenon, a blister or aggregation of Al occurs on the surface of the back-surface electrode. Further, it is also possible to prevent a failure that a crack or the like occurs in a silicon semiconductor substrate in the production process of the silicon solar cell, and hence the production efficiency of the silicon solar cell lowers.

### EXAMPLES

### Example 1

Examples of the present invention are described below. Note that the following examples are merely illustrative, and the present invention is by no means limited to the following examples.

Tables 1 to 3 show examples (Sample Nos. 1 to 18) and comparative examples (Sample Nos. 19 to 21) of the present invention.

TABLE 1

| | | Example | | | | | | | | |
|---|---|---|---|---|---|---|---|---|---|---|
| | | No. 1 | No. 2 | No. 3 | No. 4 | No. 5 | No. 6 | No. 7 | No. 8 | No. 9 |
| Glass composition | Bi₂O₃ | 85.0 | 78.3 | 79.0 | 76.0 | 77.5 | 72.0 | 66.0 | 75.0 | 70.0 |
| (mass %) | B₂O₃ | — | 4.0 | — | — | — | — | 2.0 | 1.5 | — |
| | ZnO | — | 10.5 | — | 4.0 | 4.5 | — | 2.0 | 2.0 | 8.0 |
| | SrO | — | — | — | — | — | 5.0 | 5.0 | 2.0 | 5.0 |
| | BaO | — | 6.5 | 11.0 | 12.0 | 10.0 | 15.5 | 15.0 | 11.0 | 5.0 |
| | CuO | 4.0 | — | — | — | — | — | 2.0 | 1.0 | — |
| | Fe₂O₃ | — | — | — | — | — | 0.5 | 0.5 | 0.5 | 0.5 |
| | Sb₂O₃ | 1.0 | 0.7 | 1.0 | — | 1.0 | — | 0.5 | 0.5 | 0.5 |
| | SiO₂ | 10.0 | — | 9.0 | 5.0 | 6.0 | 5.5 | 4.5 | 6.5 | 9.0 |
| | Al₂O₃ | — | — | — | 3.0 | 1.0 | 1.5 | 2.5 | — | 2.0 |

| | | | | | | | | | |
|---|---|---|---|---|---|---|---|---|---|
| Average particle diameter | 1.5 | 1.6 | 1.5 | 1.4 | 1.6 | 1.5 | 1.6 | 1.4 | 1.5 |
| D₅₀ (μm) | | | | | | | | | |
| Softening point (° C.) | 476 | 433 | 481 | 467 | 470 | 486 | 525 | 475 | 531 |
| Metal powder | Ag | Ag | Ag | Ag | Ag | Ag | Ag | Ag | Ag |
| Fire through property | ◯ | ◯ | ◯ | ◯ | ◯ | ◯ | ◯ | ◯ | ◯ |
| Cell characteristics | ◯ | Δ | ◯ | ◯ | ◯ | ◯ | Δ | ◯ | ◯ |

TABLE 2

| | | Example | | | | | | | | |
|---|---|---|---|---|---|---|---|---|---|---|
| | | No. | No. | No. | No. | No. | No. | No. | No. | No. |
| | | 10 | 11 | 12 | 13 | 14 | 15 | 16 | 17 | 18 |
| Glass composition | Bi₂O₃ | 68.5 | 77.3 | 82.0 | 86.0 | 84.0 | 84.5 | 81.0 | 85.0 | 80.0 |
| (mass %) | B₂O₃ | 1.0 | 5.0 | — | — | — | — | 3.0 | 1.0 | — |
| | ZnO | — | 10.5 | — | — | — | — | — | 5.0 | — |
| | CaO | 7.0 | — | — | — | — | — | — | — | — |
| | SrO | 7.0 | — | — | — | — | — | — | — | — |
| | BaO | 10.0 | 6.5 | — | — | 7.2 | 4.0 | 5.0 | — | — |
| | CuO | — | — | 4.0 | — | — | — | — | — | 2.0 |
| | Sb₂O₃ | — | 0.7 | 1.0 | 1.0 | 1.0 | 1.0 | — | 0.5 | 0.5 |
| | SiO₂ | 6.0 | — | 8.0 | 8.0 | 7.8 | 8.0 | 7.0 | 8.5 | 12.0 |
| | Al₂O₃ | 0.5 | — | 5.0 | 5.0 | — | 2.5 | 4.0 | — | 5.5 |

| | | | | | | | | | |
|---|---|---|---|---|---|---|---|---|---|
| Average particle diameter | 1.6 | 1.5 | 1.5 | 1.2 | 1.3 | 1.2 | 1.5 | 1.5 | 2.0 |
| D₅₀ (μm) | | | | | | | | | |
| Softening point (° C.) | 516 | 440 | 509 | 484 | 426 | 415 | 431 | 425 | 540 |
| Metal powder | Ag | Ag | Ag | Ag | Ag | Ag | Ag | Ag | Ag |
| Fire through property | ◯ | ◯ | ◯ | ◯ | ◯ | ◯ | ◯ | ◯ | ◯ |
| Cell characteristics | ◯ | Δ | ◯ | ◯ | ◯ | ◯ | ◯ | ◯ | ◯ |

TABLE 3

| | | Comparative Example | | |
|---|---|---|---|---|
| | | No. 19 | No. 20 | No. 21 |
| Glass composition | Bi₂O₃ | 65.1 | 76.3 | 55.0 |
| (mass %) | B₂O₃ | 1.9 | 6.0 | 20.0 |
| | ZnO | 10.2 | 10.5 | — |
| | CaO | 1.0 | — | — |
| | BaO | 10.0 | 6.5 | — |
| | Sb₂O₃ | — | 0.7 | — |
| | SiO₂ | 10.0 | — | 10.0 |
| | Al₂O₃ | 1.8 | — | — |
| | Na₂O | — | — | 5.0 |
| | PbO | — | — | 10.0 |

| | | | |
|---|---|---|---|
| Average particle diameter | 2.0 | 1.7 | 1.5 |
| D₅₀ (μm) | | | |
| Softening point (° C.) | 546 | 438 | 402 |
| Metal powder | Ag | Ag | Ag |
| Fire through property | x | ∘ | x |
| Cell characteristics | — | x | — |

Each sample was produced as described below. First, each glass batch was prepared by compounding glass materials such as various oxides and carbonates so as to have each of the glass compositions shown in the tables. The glass batch was loaded in a platinum crucible and melted at 900° C. to 1,200° C. for 1 to 2 hours. Next, the molten glass was formed into a film by using a water-cooling roller. The resultant glass film was pulverized in a ball mill, and the resultant pulverized glass was then passed through a sieve having a mesh size of 200 meshes. After that, air classification was carried out to yield glass powder having an average particle diameter D₅₀ shown in each of the tables.

The softening point of each sample was measured. The softening point is a value obtained by measurement with a macro-type DTA apparatus. Note that the measurement temperature range in macro-type DTA was set to room temperature to 700° C. and the temperature rise rate was set to 10° C./min.

4 mass % of the resultant glass powder, 76 mass % of metal powder shown in each of the tables (average particle diameter D₅₀=0.5 μm), and 20 mass % of a vehicle (substance obtained by dissolving an acrylic acid ester in α-terpineol) were kneaded with a three-roll mill, thereby yielding each paste-like electrode formation material. This sample was evaluated for its fire through property and cell characteristics.

The fire through property was evaluated as described below. A paste-like sample was screen-printed in a line on an SiN film (thickness: 100 nm) formed on a silicon semiconductor substrate so that the line had a length of 200 mm and a width of 100 μm, dried, and then fired in an electric furnace at 700° C. for 1 minute. Next, the resultant fired substrate was immersed in an aqueous solution of hydrochloric acid (concentration: 10 mass %). Then, an ultrasonic wave was applied for 12 hours to perform etching treatment. Subsequently, the fired substrate after the etching treatment was observed with an optical microscope (magnification: 100 times) to evaluate the fire through property. When a sample penetrated an SiN film and a linear electrode pattern was formed on a fired substrate, the sample was defined as Symbol “◯”. When a linear electrode pattern was mostly formed on a fired substrate, but portions in which a sample did not penetrate an SiN film were present, and hence electrical connection was partially disconnected, the sample was defined as Symbol “Δ”. When a sample did not penetrate an SiN film, the sample was defined as Symbol “x”.

The cell characteristics were evaluated as described below. The above-mentioned paste-like sample was used to form a light-receiving surface electrode in accordance with a usual method, followed by the production of a polycrystalline silicon solar cell. Next, the photoelectric conversion efficiency of the resultant polycrystalline silicon solar cell was measured in accordance with a usual method. The case where the photoelectric conversion efficiency was 18% or more was represented by Symbol “◯”, the case where the photoelectric conversion efficiency was 15% or more and less than 18% were represented by Symbol “Δ”, and the case where the photoelectric conversion efficiency was less than 15% was represented by Symbol “x”.

As evident from Tables 1 to 3, Sample Nos. 1 to 18 had satisfactory evaluations on the fire through property and cell characteristics. On the other hand, Sample Nos. 19 and 21 each had a glass composition out of a predetermined range and had poor evaluations on the fire through property. Note that Sample Nos. 19 and 21 had poor evaluations on the fire through property, and hence evaluations on the cell characteristics were not made. Further, Sample No. 20 had a glass composition out of a predetermined range and had a poor evaluation on the cell characteristics.

### Third Embodiment According to Related Invention

Next, a related invention of the present invention is described. This related invention has the following problems.

That is, an electrode formation material used for forming a back-surface electrode of a silicon solar cell comprises Al powder, glass powder, and a vehicle. When the electrode formation material is fired, the Al powder reacts with Si in a semiconductor substrate (silicon semiconductor substrate) in a silicon solar cell, thereby forming an Al—Si alloy layer at the interface between the back-surface electrode and the semiconductor substrate, and at the same time, forming an Al doped layer (also referred to as back surface field layer (BSF layer)) at the interface between the Al—Si alloy layer and the semiconductor substrate. The formation of the Al doped layer prevents the recombination of electrons, thereby being able to provide the effect of improving efficiency in collecting carriers produced, that is, the so-called BSF effect. As a result, the formation of the Al doped layer can enhance the photoelectric conversion efficiency of the silicon solar cell.

In this case, the glass powder comprised in the electrode formation material is a component that forms an electrode by binding particles of Al powder and is a component that is involved in the formation of an Al—Si alloy layer and an Al doped layer by influencing the reaction between the Al powder and Si (see, for example, JP 2000-90733 A and JP 2003-165744 A).

Meanwhile, a lead borate-based glass has been conventionally used as a glass for electrode formation. However, the use of the lead borate-based glass tends to be restricted from the environmental viewpoint. Thus, the actual situation is that the development of a lead-free glass for electrode formation is rapidly under way, and a bismuth-based glass is considered to be a promising substitute material for the lead borate-based glass at this moment.

However, it was difficult to form an Al—Si alloy layer and an Al doped layer each having a proper thickness by using the conventional bismuth-based glass, and hence the conventional bismuth-based glass had properties not suitable for easily enhancing the photoelectric conversion efficiency of a silicon solar cell. Specifically, when an Al doped layer formed in a semiconductor substrate has a thin thickness, a BSF effect cannot be sufficiently provided. On the other hand, when an Al doped layer is excessively formed up to in the interface between a p-type semiconductor layer and an n-type semiconductor layer in a semiconductor substrate, a depletion layer is adversely affected and a BSF effect cannot be sufficiently provided. Further, when the conventional bismuth-based glass is used, a blister or aggregation of Al is liable to occur, and a failure in outer appearance is liable to occur.

Thus, a technical object of the related invention is to invent a glass for electrode formation comprising a bismuth-based glass which is capable of properly forming an Al—Si alloy layer and an Al doped layer while preventing the occurrence of a blister or aggregation of Al, thereby reducing the occurrence of a failure in outer appearance of a silicon solar cell and enhancing the photoelectric conversion efficiency of the silicon solar cell.

The glass for electrode formation according to the third embodiment of the related invention, the glass being invented for achieving the above-mentioned object, comprises, as a glass composition in terms of mass %, 56 to 76.3% of Bi₂O₃, 2 to 18% of B₂O₃, 0 to 11% of ZnO (provided that 11% is not included), 0 to 12% of CaO, and 0 to 25% of BaO+CuO+Fe₂O₃+Sb₂O₃, and has a softening point of 462 to 520° C.

The reasons why the content ranges of the respective components were limited to those described above are as described below. Note that in the description about the glass composition, “%” refers to “mass %.”

Bi₂O₃ is a component that lowers the softening point of glass and is also a component that enhances the water resistance of glass. The content of Bi₂O₃ is 56 to 76.3%, preferably 60 to 76%, more preferably 65 to 75%, still more preferably 67 to 73%. When the content of Bi₂O₃ is less than 56% in glass, the softening point thereof becomes too high, the glass is difficult to melt at the time of firing, and hence the reaction between Al powder and Si becomes excessive, with the result that an Al—Si alloy layer and an Al doped layer are excessively formed and the photoelectric conversion efficiency of a silicon solar cell is liable to deteriorate. Further, the sintering property of a back-surface electrode deteriorates, and hence the mechanical strength of the back-surface electrode is liable to lower. Further, when the content of Bi₂O₃ is less than 56% in glass, the water resistance is liable to lower, with the result that the long-term stability of a silicon solar cell is liable to deteriorate. On the other hand, when the content of Bi₂O₃ is more than 76.3% in glass, the softening point thereof lowers excessively, and the glass inhibits the reaction between Al powder and Si at the time of firing, with the result that an Al—Si alloy layer and an Al doped layer are hardly formed. Further, when the content of Bi₂O₃ is more than 76.3% in glass, the thermal stability thereof deteriorates, the glass is liable to denitrify at the time of firing, and the mechanical strength of a back-surface electrode is liable to lower. Further, when the glass fully devitrifies at the time of firing, a proper reaction between Al powder and Si hardly occurs and a BSF effect is hardly provided.

B₂O₃ is a component that forms a skeleton of glass. The content of B₂O₃ is 2 to 18%, preferably 5 to 16%, still more preferably 8 to 15%, particularly preferably 10 to 14%. When the content of B₂O₃ is less than 2% in glass, the thermal stability thereof deteriorates, the glass is liable to denitrify at the time of firing, and hence the mechanical strength of a back-surface electrode is liable to lower. Further, when the glass fully devitrifies at the time of firing, a proper reaction between Al powder and Si hardly occurs and is BSF effect is hardly provided. On the other hand, when the content of B₂O₃ is more than 18% in glass, the water resistance is liable to lower, with the result that the long-term stability of a silicon solar cell is liable to deteriorate, and phase separation is liable to occur in the glass, with the result that it is difficult to uniformly form an Al—Si alloy layer and an Al doped layer.

ZnO is a component that enhances the thermal stability of glass and is also a component that lowers the softening point of glass without increasing the thermal expansion coefficient thereof. The content of ZnO is 0 to 11% (provided that 11% is not included), preferably 0.1 to 10%, more preferably 1 to 9%. When the content of ZnO is 11% or more in glass, the balance of components in a glass composition is lost, with the result that the thermal stability thereof is liable to deteriorate and a blister or aggregation of Al is liable to occur to the worse. Note that from the viewpoint of suppressing the occurrence of a blister or aggregation of Al, it is preferred that glass be substantially free of ZnO. Herein, the phrase “substantially free of ZnO” refers to the case where the content of ZnO in a glass composition is 1,000 ppm or less.

CaO is a component that has a large effect of suppressing the occurrence of a blister or aggregation of Al. The content of CaO is preferably 0 to 12%, 0 to 10%, 0.1 to 8%, 0.5 to 5%, particularly preferably 1 to 4%. When the content of CaO is more than 12% in glass, the softening point thereof becomes too high, the glass is difficult to melt at the time of firing, and hence the reaction between Al powder and Si becomes excessive, with the result that an Al—Si alloy layer and an Al doped layer are excessively formed and the photoelectric conversion efficiency of a silicon solar cell is liable to deteriorate. Further, the sintering property of a back-surface electrode deteriorates, and hence the mechanical strength of the back-surface electrode is liable to lower.

BaO+CuO+Fe₂O₃+Sb₂O₃ are components that enhance the thermal stability of glass. The content of the BaO+CuO+Fe₂O₃+Sb₂O₃ is 0 to 25%, preferably 1 to 20%, more preferably 4 to 15%, still more preferably 6 to 12%. When the content of BaO+CuO+Fe₂O₃+Sb₂O₃ is more than 25% in glass, the balance of components in a glass composition is lost, with the result that the thermal stability thereof deteriorates and the glass is liable to denitrify at the time of firing to the worse. As a result, the mechanical strength of a back-surface electrode is liable to lower. Further, when the glass fully devitrifies at the time of firing, a proper reaction between Al powder and Si hardly occurs and a BSF effect is hardly provided.

BaO is a component that suppresses the occurrence of a blister or aggregation of Al and is also a component that remarkably enhances the thermal stability of glass. The content of BaO is preferably 0 to 20%, 0.01 to 15%, 0.1 to 10%, 1 to 9%, particularly preferably 2 to 8%. When the content of BaO is more than 20% in glass, the balance of components in a glass composition is lost, with the result that the thermal stability thereof deteriorates to the worse. Further, when the glass fully devitrifies at the time of firing, a proper reaction between Al powder and Si hardly occurs and a BSF effect is hardly provided.

CuO is a component that remarkably enhances the thermal stability of glass and is a component that lowers the softening point of glass without increasing the thermal expansion coefficient thereof. The content of CuO is preferably 0 to 12%, 0.1 to 9%, particularly preferably 1 to 7%. When the content of CuO is more than 12% in glass, the balance of components in a glass composition is lost, with the result that the thermal stability thereof is liable to deteriorate to the worse. Further, when the glass fully devitrifies at the time of firing, a proper reaction between Al powder and Si hardly occurs and a BSF effect is hardly provided.

ZnO+CuO are components that remarkably enhance the thermal stability of glass and is a component that lowers the softening point of glass without increasing the thermal expansion coefficient thereof. The content of ZnO+CuO is preferably 0 to 20%, 2.6 to 16%, 3 to 14%, particularly preferably 5 to 12%. When the content of ZnO+CuO is more than 20% in glass, the balance of components in a glass composition is lost, with the result that the thermal stability thereof is liable to deteriorate and a blister or aggregation of Al is liable to occur to the worse.

Fe₂O₃ is a component that enhances the thermal stability of glass. The content of Fe₂O₃ is preferably 0 to 7%, 0.1 to 4%, particularly preferably 0.4 to 3%. When the content of Fe₂O₃ is more than 7% in glass, the balance of components in a glass composition is lost, with the result that the thermal stability of the glass tends to deteriorate to the worse. Further, when the glass fully devitrifies at the time of firing, a proper reaction between Al powder and Si hardly occurs and a BSF effect is hardly provided.

Sb₂O₃ is a component that remarkably enhances the thermal stability of glass. The content of Sb₂O₃ is preferably 0 to 7%, 0.1 to 0.4%, particularly preferably 0.5 to 3%. When the content of Sb₂O₃ is more than 7% in glass, the balance of components in a glass composition is lost, with the result that the thermal stability of the glass tends to deteriorate to the worse. Further, when the glass fully devitrifies at the time of firing, a proper reaction between Al powder and Si hardly occurs and a BSF effect is hardly provided.

In addition to the above-mentioned components, for example, the following components may be added.

MgO is a component that suppresses the occurrence of a blister or aggregation of Al. The content of MgO is preferably 0 to 5%, 0 to 3%, particularly preferably 0 to 1%. When the content of MgO is more than 5% in glass, the softening point thereof becomes too high, the glass is difficult to melt at the time of firing, and hence the reaction between Al powder and Si becomes excessive, with the result that an Al—Si alloy layer and an Al doped layer are excessively formed and the photoelectric conversion efficiency of a silicon solar cell is liable to deteriorate. Further, the sintering property of a back-surface electrode deteriorates, and hence the mechanical strength of the back-surface electrode is liable to lower.

SrO is a component that suppresses the occurrence of a blister or aggregation of Al and is also a component that enhances the thermal stability of glass. The content of SrO is preferably 0 to 15%, 0 to 10%, particularly preferably 0 to 5%. When the content of SrO is more than 15% in glass, the balance of components in a glass composition is lost, with the result that the thermal stability thereof is liable to deteriorate to the worse.

SiO₂ is a component that enhances the water resistance of glass, but has an action of significantly increasing the softening point thereof. Thus, the content of SiO₂ is preferably 20% or less, 15% or less, 8.5% or less, 5% or less, 3% or less, particularly preferably 1% or less. When the content of SiO₂ is more than 20% in glass, the softening point thereof becomes too high, the glass is difficult to melt at the time of firing, and hence the reaction between Al powder and Si becomes excessive, with the result that an Al—Si alloy layer and an Al doped layer are excessively formed and the photoelectric conversion efficiency of a silicon solar cell is liable to deteriorate. Further, the sintering property of a back-surface electrode deteriorates, and hence the mechanical strength of the back-surface electrode is liable to lower.

Al₂O₃ is a component that enhances the water resistance of glass, but has an action of significantly increasing the softening point thereof. Thus, the content of Al₂O₃ is preferably 15% or less, 8.5% or less, 5% or less, 3% or less, particularly preferably 1% or less. When the content of Al₂O₃ is more than 15% in glass, the softening point thereof becomes too high, the glass is difficult to melt at the time of firing, and hence the reaction between Al powder and Si becomes excessive, with the result that an Al—Si alloy layer and an Al doped layer are excessively formed and the photoelectric conversion efficiency of a silicon solar cell is liable to deteriorate. Further, the sintering property of a back-surface electrode deteriorates, and hence the mechanical strength of the back-surface electrode is liable to lower.

Li₂O, Na₂O, K₂O, and Cs₂O are components that lower the softening point of glass, but have an action of promoting the denitrification of glass at the time of melting. The content of each of Li₂O, Na₂O, K₂O, and Cs₂O is preferably 2% or less.

Nd₂O₃ is a component that enhances the thermal stability of glass. The content of Nd₂O₃ is preferably 0 to 10%, 0 to 5%, particularly preferably 0 to 3%. When Nd₂O₃ is added in a predetermined amount in a glass composition, the glass network of a Bi₂O₃—B₂O₃-based glass is stabilized, and crystals of Bi₂O₃ (bismite) or crystals of 2Bi₂O₃.B₂O₃, 12Bi₂O₃.B₂O₃, or the like formed of Bi₂O₃ and B₂O₃ become unlikely to precipitate at the time of firing. Note that when the content of Nd₂O₃ is more than 10% in glass, the balance of components in a glass composition is lost, with the result that the crystals are liable to precipitate in the glass to the worse.

WO₃ is a component that enhances the thermal stability of glass. The content of WO₃ is preferably 0 to 5%, particularly preferably 0 to 2%. When the content of WO₃ is more than 5% in glass, the balance of components in a glass composition is lost, with the result that the thermal stability of the glass is liable to lower to the worse.

In₂O₃ is a component that enhances the thermal stability of glass. The content of In₂O₃ is preferably 0 to 3%, particularly preferably 0 to 1%. When the content of In₂O₃ is more than 5% in glass, the batch cost of the glass soars.

Ga₂O₃ is a component that enhances the thermal stability of glass. The content of Ga₂O₃ is preferably 0 to 3%, particularly preferably 0 to 1%. When the content of Ga₂O₃ is more than 5% in glass, the batch cost of the glass soars.

P₂O₅ is a component that suppresses the denitrification of glass at the time of melting. However, when the content of P₂O₅ is large in glass, the phase separation of the glass is liable to occur, with the result that it is difficult to uniformly form an Al—Si alloy layer and an Al doped layer. Thus, the content of P₂O₅ is preferably 1% or less.

MoO₃+La₂O₃+Y₂O₃+CeO₂ (total content of MoO₃, La₂O₃, Y₂O₃, and CeO₂) have an effect of suppressing the phase separation at the time of melting. However, when the content of those components is large in glass, the batch cost of the glass soars. Thus, the content of MoO₃+La₂O₃+Y₂O₃+CeO₂ is preferably 3% or less. Note that the content of each of MoO₃, La₂O₃, Y₂O₃, and CeO₂ is preferably 0 to 2%.

The glass for electrode formation according to the third embodiment may comprise PbO, but is preferably substantially free of PbO from the environmental viewpoint.

The glass for electrode formation according to the third embodiment has a softening point of 462 to 520° C., preferably 465 to 510° C., more preferably 470 to 500° C. When glass has a softening point of less than 462° C., the glass inhibits the reaction between Al powder and Si at the time of firing, and hence an Al—Si alloy layer and an Al doped layer are hardly formed, with the result that a BSF effect is hardly provided. On the other hand, when glass has a softening point of more than 520° C., the glass is difficult to melt at the time of firing, and hence the reaction between Al powder and Si becomes excessive, with the result that an Al—Si alloy layer and an Al doped layer are excessively formed and the photoelectric conversion efficiency of a silicon solar cell is liable to deteriorate, and a blister or aggregation of Al is liable to occur.

### Fourth Embodiment According to Related Invention

The electrode formation material according to the fourth embodiment as a related invention comprises glass powder comprising the glass for electrode formation according to the third embodiment, metal powder, and a vehicle. The glass powder is a component that forms an electrode by binding particles of Al powder and is a component that causes an Al—Si alloy layer and an Al doped layer to be formed properly by influencing the reaction between Al powder and Si. The metal powder is a main component for forming an electrode and a component for securing conductivity. The vehicle is a component for converting the electrode formation material into a paste form and a component for imparting viscosity suitable for printing.

In the electrode formation material according to the fourth embodiment, the average particle diameter D₅₀ of the glass powder is preferably 3 μm or less, 2 μm or less, particularly preferably 1.5 μm or less. When the average particle diameter D₅₀ of the glass powder is more than 3 μm, the formation of a fine electrode pattern becomes difficult, and hence the photoelectric conversion efficiency of a silicon solar cell is liable to lower. On the other hand, although the lower limit of the average particle diameter D₅₀ of the glass powder is not particularly limited, when the average particle diameter D₅₀ of the glass powder is too small, the handleability of the glass powder and the material yield are liable to lower. When the circumstances described above are taken into consideration, the average particle diameter D₅₀ of the glass powder is preferably 0.5 μm or more. Note that (1) when a glass film is pulverized in a ball mill and the resultant glass powder is then subjected to air classification, or (2) when a glass film is roughly pulverized in a ball mill or the like and the resultant glass is then subjected to wet pulverization in a bead mill or the like, the glass powder having the above-mentioned average particle diameter D₅₀ can be produced.

In the electrode formation material according to the fourth embodiment, the maximum particle diameter Dₘₐₓ of the glass powder is preferably 25 μm or less, 20 μm or less, 15 μm or less, 10 μm or less, particularly preferably less than 10 μm. When the maximum particle diameter Dₘₐₓ of the glass powder is more than 25 μm, the formation of a fine electrode pattern becomes difficult, and hence the photoelectric conversion efficiency of a silicon solar cell is liable to lower. Herein, the term “maximum particle diameter Dₘₐₓ” refers to a value obtained by measurement by laser diffractometry, and refers to a particle diameter at which the cumulative amount of particles starting from a particle having the smallest diameter reaches 99% in a cumulative particle size distribution curve in terms of volume prepared based on the measurement by laser diffractometry.

In the electrode formation material according to the fourth embodiment, the crystallization temperature of the glass powder is preferably 550° C. or more, 580° C. or more, particularly preferably 600° C. or more. When the crystallization temperature of the glass powder is less than 550° C., the thermal stability of glass lowers, with the result that the glass is liable to denitrify at the time of firing and the mechanical strength of a back-surface electrode is liable to lower. Further, when glass fully devitrifies, a proper reaction between Al powder and Si hardly occurs and a BSF effect is hardly provided. Herein, the term “crystallization temperature” refers to a peak temperature measured with a macro-type DTA apparatus, and in DTA, the measurement starts from room temperature and the temperature rise rate is set to 10° C./min.

In the electrode formation material according to the fourth embodiment, the content of the glass powder is preferably 0.2 to 10 mass %, 0.5 to 6 mass %, 0.7 to 4 mass %, particularly preferably 1 to 3 mass %. When the content of the glass powder is less than 0.2 mass %, a blister or aggregation of Al is liable to occur, and moreover, the mechanical strength of a back-surface electrode is liable to lower. On the other hand, when the content of the glass powder is more than 10 mass %, segregation of glass is liable to occur after firing, and hence the conductivity of a back-surface electrode lowers, with the result that the photoelectric conversion efficiency of a silicon solar cell may lower. Further, because of the same reasons as those described above, the mass ratio between the contents of the glass powder and the metal powder is preferably 0.3:99.7 to 13:87, 1.5:98.5 to 7:93, particularly preferably 1.8:98.2 to 4:96.

In the electrode formation material according to the fourth embodiment, the volume ratio between the contents of the glass powder and the metal powder is preferably 1:99 to 10:90, 2:98 to 6:94, particularly preferably 2.5:97.5 to 5:95. When the content of the glass powder is smaller, a blister or aggregation of Al is liable to occur, and moreover, the mechanical strength of a back-surface electrode is liable to lower. On the other hand, when the content of the glass powder is larger, segregation of glass is liable to occur after firing, and hence the conductivity of a back-surface electrode lowers, with the result that the photoelectric conversion efficiency of a silicon solar cell may lower.

In the electrode formation material according to the fourth embodiment, the content of the metal powder is preferably 50 to 97 mass %, 65 to 95 mass %, particularly preferably 70 to 92 mass %. When the content of the metal powder is less than 50 mass %, the conductivity of aback-surface electrode lowers, with the result that the photoelectric conversion efficiency of a silicon solar cell is liable to lower. On the other hand, when the content of the metal powder is more than 97 mass %, the content of the glass powder relatively lowers, and hence it is difficult to properly form an Al—Si alloy layer and an Al doped layer.

In the electrode formation material according to the fourth embodiment, the metal powder is preferably one kind of powder or two or more kinds of powders of Ag, Al, Au, Cu, Pd, Pt, and alloys thereof. Al powder is particularly preferred from the viewpoint of providing a BSF effect. Any of those metal powders has satisfactory conductivity and has satisfactory compatibility with the bismuth-based glass according to the present invention. Thus, when any of those metal powders is used, glass becomes unlikely to produce bubbles and glass becomes unlikely to denitrify at the time of firing. Further, from the viewpoint of forming a fine electrode pattern, the average particle diameter D₅₀ of the metal powder is preferably 5 μm or less, 3 μm or less, 2 μm or less, particularly preferably 1 μm or less.

In the electrode formation material according to the fourth embodiment, the content of the vehicle is preferably 5 to 50 mass %, particularly preferably 10 to 30 mass %. When the content of the vehicle is less than 5 mass %, it is difficult to convert the electrode formation material into a paste form, and hence it is difficult to form an electrode by a thick-film method. On the other hand, when the content of the vehicle is more than 50 mass %, a film thickness and a film width are liable to vary before and after firing, and hence it is difficult to form a desired electrode pattern.

As described above, the term “vehicle” generally refers to a substance obtained by dissolving a resin in an organic solvent. Further, as specific examples of the organic solvent and the resin, there may be used the same organic solvent and resin as in the vehicle described in the second embodiment.

The electrode formation material of the present invention may comprise, in addition to the above-mentioned components, ceramic filler powder such as cordierite powder for adjusting the thermal expansion coefficient of glass, oxide powder such as NiO powder for adjusting the surface resistance of an electrode, a surfactant, a thickener, a plasticizer, and a surface treatment agent each for adjusting a paste characteristic, a pigment for adjusting a color tone, and the like.

The electrode formation material according to the fourth embodiment (or the glass for electrode formation according to the third embodiment) is suitable for forming a back-surface electrode, but may be used for forming a light-receiving surface electrode. When the light-receiving surface electrode is formed by a thick-film method, through utilization of such a phenomenon that an electrode formation material penetrates an anti-reflective film at the time of firing, the light-receiving surface electrode is electrically connected to a semiconductor layer. The phenomenon is generally referred to as fire through. Through utilization of the fire through, it becomes unnecessary to etch the anti-reflective film, and moreover, it becomes unnecessary to position an etching on the anti-reflective film with an electrode pattern, when the light-receiving surface electrode is formed. As a result, the production efficiency of a silicon solar cell improves dramatically. The degree of how much the electrode formation material penetrates the anti-reflective film (hereinafter, referred to as fire through property) varies depending on the composition of the electrode formation material and a firing condition, and in particular, is influenced most significantly by the glass composition of glass powder. In addition, the photoelectric conversion efficiency of the silicon solar cell has a correlation with the fire through property of the electrode formation material. When the fire through property is poor, the characteristics lower. As a result, the fundamental performance of the silicon solar cell lowers. In the electrode formation material of the present invention, the glass composition range of the glass powder is controlled as described above, and hence the electrode formation material has satisfactory fire through property and is suitable for forming the light-receiving surface electrode. When the electrode formation material of the present invention is used for forming the light-receiving surface electrode, Ag powder is preferably used as the metal powder. The content or the like of the Ag powder is as described above.

The light-receiving surface electrode and the back-surface electrode may be formed separately, or the light-receiving surface electrode and the back-surface electrode may be formed at the same time. When the light-receiving surface electrode and the back-surface electrode are formed at the same time, the frequency of firing can be reduced, and hence the production efficiency of the silicon solar cell improves. In this case, when the electrode formation material of the present invention is used for both the light-receiving surface electrode and the back-surface electrode, it becomes easy to form the light-receiving surface electrode and the back-surface electrode at the same time.

### Example 2

Examples of related inventions are described below.

Tables 4 and 5 show examples (Sample Nos. 22 to 31) and comparative examples (Sample Nos. 32 to 34) of the related inventions.

TABLE 4

| | | Example | | | | | | | | |
|---|---|---|---|---|---|---|---|---|---|---|
| | | No. | No. | No. | No. | No. | No. | No. | No. | No. |
| | | 22 | 23 | 24 | 25 | 26 | 27 | 28 | 29 | 30 |
| Glass composition | Bi₂O₃ | 76.0 | 75.0 | 75.0 | 76.0 | 75.0 | 71.2 | 69.0 | 62.0 | 72.5 |
| (mass %) | B₂O₃ | 8.1 | 16.5 | 18.0 | 12.2 | 16.0 | 12.3 | 10.0 | 5.0 | 10.5 |
| | ZnO | 6.8 | — | 2.0 | 5.0 | 1.0 | 7.6 | 10.0 | 5.5 | 6.0 |
| | CaO | 5.8 | — | 0.5 | — | — | — | — | 3.0 | 2.0 |
| | BaO | — | 3.5 | — | — | 3.0 | 3.0 | 6.0 | 15.0 | 5.0 |
| | CuO | 2.2 | 3.0 | 2.0 | 4.8 | 2.0 | 4.6 | 3.9 | 5.0 | — |
| | Fe₂O₃ | 0.5 | — | — | — | 0.5 | 0.6 | 0.5 | 0.5 | 1.0 |
| | Sb₂O₃ | 0.6 | — | — | 0.7 | 0.5 | 0.7 | 0.6 | 0.5 | 1.0 |
| | SiO₂ | — | 1.5 | 2.0 | 0.5 | 2.0 | — | — | 2.5 | 1.0 |
| | Al₂O₃ | — | 0.5 | 0.5 | 0.8 | — | — | — | 1.0 | 1.0 |

| | | | | | | | | | |
|---|---|---|---|---|---|---|---|---|---|
| α (×10⁻⁷/° C.) | 97 | 89 | 85 | 94 | 87 | 94 | 93 | 85 | 90 |
| D₅₀ (μm) | 1.6 | 1.3 | 1.4 | 1.5 | 1.5 | 1.5 | 1.6 | 1.4 | 1.7 |
| Softening point (° C.) | 465 | 497 | 515 | 474 | 513 | 470 | 475 | 518 | 493 |
| Thermal stability | ◯ | ◯ | ◯ | ◯ | ◯ | ◯ | ◯ | ◯ | ◯ |
| Al doped layer | ◯ | ◯ | ◯ | ◯ | ◯ | ◯ | ◯ | ◯ | ◯ |
| Outer appearance | ◯ | ◯ | ◯ | ◯ | ◯ | ◯ | ◯ | ◯ | ◯ |
| Cell characteristics | ◯ | ◯ | ◯ | ◯ | ◯ | ◯ | ◯ | ◯ | ◯ |

TABLE 5

| | | Example | Comparative Example | | |
|---|---|---|---|---|---|
| | | No. 31 | No. 32 | No. 33 | No. 34 |
| Glass composition | Bi₂O₃ | 71.0 | 77.5 | 64.5 | 65.0 |
| (mass %) | B₂O₃ | 13.0 | 8.5 | 30.5 | 25.0 |
| | ZnO | 8.0 | 7.7 | — | 4.0 |
| | CaO | 2.0 | — | — | — |
| | BaO | — | 4.3 | — | 4.0 |
| | CuO | 4.0 | 1.0 | 2.5 | 1.0 |
| | Fe₂O₃ | 0.5 | 0.5 | — | 0.5 |
| | Sb₂O₃ | 0.5 | 0.5 | — | 0.5 |
| | SiO₂ | — | — | 2.0 | — |
| | Al₂O₃ | 1.0 | — | 0.5 | — |

| | | | | |
|---|---|---|---|---|
| α (×10⁻⁷/° C.) | 92 | 104 | 82 | 80 |
| D₅₀ (μm) | 1.6 | 1.4 | 1.5 | 1.4 |
| Softening point (° C.) | 484 | 450 | 530 | 542 |
| Thermal stability | ∘ | ∘ | ∘ | ∘ |
| Al doped layer | ∘ | x | x | x |
| Outer appearance | ∘ | ∘ | x | x |
| Cell characteristics | ∘ | x | x | x |

Each sample was produced as described below. First, each glass batch was prepared by compounding glass materials such as various oxides and carbonates so as to have each of the glass compositions shown in the tables. The glass batch was loaded in a platinum crucible and melted at 1,000 to 1,100° C. for 1 to 2 hours. Next, part of the molten glass was extruded in a mold made of stainless steel to produce a sample for push-rod-type thermomechanical analysis (TMA). The remainder of the molten glass was formed into a film by using a water-cooling roller. The resultant glass film was pulverized in a ball mill, and the resultant pulverized glass was then passed through a sieve having a mesh size of 250 meshes. After that, classification was carried out to yield glass powder having an average particle diameter D₅₀ shown in each of the tables.

Each sample was measured for its thermal expansion coefficient α, average particle diameter D₅₀, softening point, thermal stability, state of an Al doped layer, outer appearance, and cell characteristics. Tables 1 and 2 show the results.

The thermal expansion coefficient α is a value obtained by measurement in the temperature range of 30 to 300° C. with a TMA apparatus.

The average particle diameter D₅₀ refers to a value obtained by measurement by laser diffractometry, and refers to a particle diameter at which the cumulative amount of particles starting from a particle having the smallest diameter reaches 50% in a cumulative particle size distribution curve in terms of volume prepared based on the measurement by laser diffractometry.

The softening point is a value obtained by measurement with a macro-type DTA apparatus. Note that the measurement temperature range in macro-type DTA was set to room temperature to 650° C. and the temperature rise rate was set to 10° C./min.

The thermal stability was evaluated as follows: a sample having a crystallization temperature of 550° C. or more was defined as Symbol “◯”; and a sample having a crystallization temperature of less than 550° C. was defined as Symbol “x”. Note that the crystallization temperature is a value obtained by measurement with the macro-type DTA apparatus. The measurement temperature range in macro-type DTA was set to room temperature to 650° C. and the temperature rise rate was set to 10° C./min.

3 mass % of the resultant glass powder, 75 mass % of Al powder (average particle diameter D₅₀=0.5 μm), and 23 mass % of a vehicle (substance obtained by dissolving an acrylic acid ester in α-terpineol) were kneaded with a three-roll mill, thereby yielding a paste-like electrode formation material. Next, the electrode formation material was applied onto the entire surface on the n-type semiconductor layer side as the back surface of a silicon semiconductor substrate (100 mm by 100 mm by 200 μm in thickness) by screen printing, followed by drying. After that, the silicon semiconductor substrate was fired at the maximum temperature of 720° C. for a short time (for 2 minutes from the start of the firing to the finish and the maximum temperature was kept for 20 seconds), yielding a back-surface electrode having a thickness of 50 μm. The resultant back-surface electrode was visually observed for its surface, and evaluated for its outer appearance by observing the numbers of blisters and aggregations of Al in the surface. Specifically, the evaluation was performed as follows: the case where the numbers of blisters and aggregations of Al were 2 or less was defined as Symbol “◯”; the case where the numbers of blisters and aggregations of Al were 3 to 5 was defined as Symbol “Δ”; and the case where the numbers of blisters and aggregations of Al were 6 or more was defined as Symbol “x”.

The state of an Al doped layer was evaluated as described above. Each back-surface electrode produced for evaluating its outer appearance was observed by SEM (mapping). The case where an Al doped layer was formed up to just before the pn junction in a silicon semiconductor substrate was defined as Symbol “◯”, and the other cases were defined as Symbol “x”.

The cell characteristics were evaluated as described above. The above-mentioned paste-like sample was used to form a back-surface electrode in accordance with a usual method, followed by the production of a silicon solar cell. Next, the photoelectric conversion efficiency of the resultant polycrystalline silicon solar cell was measured in accordance with a usual method. The case where the photoelectric conversion efficiency was 17% or more was defined as Symbol “◯”, and the case where the photoelectric conversion efficiency was less than 17% was defined as Symbol “x”.

As evident from Tables 4 and 5, Sample Nos. 22 to 31 had satisfactory evaluations on the Al doped layer, outer appearance, and cell characteristics. On the other hand, Sample No. 32 had a low softening point, and hence had a poor evaluation on the Al doped layer. Sample Nos. 33 and 34 each had a high softening point, and hence had a poor evaluation on the cell characteristics.

### INDUSTRIAL APPLICABILITY

The glass for electrode formation and electrode formation material of the present invention may be suitably used for an electrode of a silicon solar cell, in particular, a light-receiving surface electrode of a silicon solar cell having an anti-reflective film. Further, the glass for electrode formation and electrode formation material of the present invention are applicable to applications other than the silicon solar cell, including ceramic electronic parts such as a ceramic condenser and optical parts such as a photodiode.

1. A glass for electrode formation, comprising, as a glass composition in terms of mass %, 65.2 to 90% of Bi₂O₃, 0 to 5.4% of B₂O₃, and 0.1 to 34.5% of MgO+CaO+SrO+BaO+ZnO+CuO+Fe₂O₃+Nd₂O₃+CeO₂+Sb₂O₃.

2. The glass for electrode formation according to claim 1, wherein the glass for electrode formation has a content of B₂O₃ of 1.9 mass % or less.

3. The glass for electrode formation according to claim 1, wherein the glass for electrode formation is substantially free of B₂O₃.

4. The glass for electrode formation according to claim 1, further comprising 0.1 to 15 mass % of SiO₂+Al₂O₃.

5. The glass for electrode formation according to claim 1, wherein the glass for electrode formation is substantially free of PbO.

6. An electrode formation material, comprising glass powder comprising the glass for electrode formation according to claim 1, metal powder, and a vehicle.

7. The electrode formation material according to claim 6, wherein the glass powder has an average particle diameter D₅₀ of less than 5 μm.

8. The electrode formation material according to claim 6, wherein the glass powder has a softening point of 550° C. or less.

9. The electrode formation material according to claim 6, wherein a content of the glass powder is 0.2 to 10 mass %.

10. The electrode formation material according to claim 6, wherein the metal powder comprises one kind of powder or two or more kinds of powders of Ag, Al, Au, Cu, Pd, Pt, and alloys thereof.

11. The electrode formation material according to claim 6, wherein the electrode formation material is used for an electrode of a silicon solar cell.

12. The electrode formation material according to claim 6, wherein the electrode formation material is used for a light-receiving surface electrode of a silicon solar cell having an anti-reflective film.

13. The glass for electrode formation according to claim 2, wherein the glass for electrode formation is substantially free of B₂O₃.

14. The glass for electrode formation according to claim 2, further comprising 0.1 to 15 mass % of SiO₂+Al₂O₃.

15. The glass for electrode formation according to claim 3, further comprising 0.1 to 15 mass % of SiO₂+Al₂O₃.

16. The glass for electrode formation according to claim 13, further comprising 0.1 to 15 mass % of SiO₂+Al₂O₃.

17. The glass for electrode formation according to claim 2, wherein the glass for electrode formation is substantially free of PbO.

18. The glass for electrode formation according to claim 3, wherein the glass for electrode formation is substantially free of PbO.

19. The glass for electrode formation according to claim 4, wherein the glass for electrode formation is substantially free of PbO.

20. The glass for electrode formation according to claim 13, wherein the glass for electrode formation is substantially free of PbO.
